(19) United States
(12) Patent Application Publication
(10) Pub. No.: US 2021/0143253 A1
(43) Pub. Date: May 13, 2021

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Mariko Yamashita, Yokohama Kanagawa (JP); Kanako Komatsu, Yokohama Kanagawa (JP); Yoshiaki Ishii, Kawasaki Kanagawa (JP); Daisuke Shinohara, Yokohama Kanagawa (JP)

(21) Appl. No.: 16/926,989

(22) Filed: Jul. 13, 2020

(30) Foreign Application Priority Data
Nov. 8, 2019 (JP) 2019-203060

(51) Int. Cl. H01L 29/06; H01L 29/78

(52) U.S. Cl. CPC H01L 29/0623; H01L 29/7816

(57) ABSTRACT

A semiconductor device includes a semiconductor substrate of a first conductivity type, a semiconductor layer of the first conductivity type provided on the semiconductor substrate, a first deep semiconductor region of a second conductivity type provided between the semiconductor substrate and the semiconductor layer, a first guard ring region of the second conductivity type, a first separation region of the second conductivity type contacting the first guard ring region and the first deep semiconductor region, a first semiconductor region of the first conductivity type, and a second semiconductor region of the first conductivity type; the first guard ring region and the first deep semiconductor region surround a first device part of the semiconductor layer; the first separation region partitions the first device part into a first region and a second region; and the first and second semiconductor regions are provided in the first and second regions.

### CROSS-REFERENCE TO RELATED APPLICATIONS

This application is based upon and claims the benefit of priority from Japanese Patent Application No. 2019-203060, filed on Nov. 8, 2019; the entire contents of which are incorporated herein by reference.

### FIELD

Embodiments relate to a semiconductor device.

### BACKGROUND

There are cases where a circuit such as a power control circuit or the like handling a large current and a circuit such as a signal processing circuit or the like handling a small current are provided together in a semiconductor device. In such a semiconductor device, there are cases where noise generated in the large current circuit affects the operation of the small current circuit. Therefore, technology has been proposed in which a guard ring region is provided at the periphery of the large current circuit to electrically isolate the large current circuit from the periphery.

However, even if a guard ring region is provided at the periphery of the large current circuit, there are cases where the noise leaks outside the guard ring region and interferes with the small current circuit in the periphery. To suppress such interference, it is necessary to increase the distance between the circuits; and downsizing of the semiconductor device is inhibited.

### BRIEF DESCRIPTION OF THE DRAWINGS

FIG. 1 is a plan view showing a semiconductor device according to a first embodiment;

FIG. 2 is a cross-sectional view showing the semiconductor device according to the first embodiment;

FIG. 3 shows an operation of the semiconductor device according to the first embodiment;

FIG. 4 is a plan view showing a semiconductor device according to a first modification of the first embodiment;

FIG. 5 is a plan view showing a semiconductor device according to a second modification of the first embodiment;

FIG. 6 is a plan view showing a semiconductor device according to a third modification of the first embodiment;

FIG. 7 is a plan view showing a semiconductor device according to a fourth modification of the first embodiment;

FIG. 8 is a plan view showing a semiconductor device according to a fifth modification of the first embodiment;

FIG. 9 is a plan view showing a semiconductor device according to a sixth modification of the first embodiment;

FIG. 10 is a plan view showing a semiconductor device according to a second embodiment;

FIG. 11 is a cross-sectional view showing the semiconductor device according to the second embodiment;

FIG. 12 is a plan view showing a semiconductor device according to a third embodiment;

FIG. 13 is a cross-sectional view showing the semiconductor device according to the third embodiment;

FIG. 14 is a plan view showing a semiconductor device according to a fourth embodiment;

FIG. 15A is a plan view showing a semiconductor device according to a fifth embodiment; and FIG. 15B is a cross-sectional view of the semiconductor device according to the fifth embodiment;

FIG. 16 is a plan view showing a semiconductor device according to a sixth embodiment; and

FIG. 17 is a plan view showing a semiconductor device according to a seventh embodiment.

### DETAILED DESCRIPTION

A semiconductor device according to an embodiment includes a semiconductor substrate of a first conductivity type, a semiconductor layer of the first conductivity type provided on the semiconductor substrate, a first deep semiconductor region of a second conductivity type provided between the semiconductor substrate and the semiconductor layer, a first guard ring region of the second conductivity type, a first separation region of the second conductivity type contacting the first guard ring region and the first deep semiconductor region, a first semiconductor region of the first conductivity type, and a second semiconductor region of the first conductivity type; the first guard ring region and the first deep semiconductor region surround a first device part of the semiconductor layer; the first separation region partitions the first device part into a first region and a second region; the first semiconductor region is provided in the first region; and the second semiconductor region is provided in the second region.

A semiconductor device according to an embodiment includes a semiconductor substrate of a first conductivity type, a semiconductor layer of the first conductivity type provided on the semiconductor substrate, a first deep semiconductor region of a second conductivity type provided between the semiconductor substrate and the semiconductor layer, a first guard ring region of the second conductivity type, and a first semiconductor region of the first conductivity type; the first guard ring region and the first deep semiconductor region surround a first device part of the semiconductor layer; and the first semiconductor region is provided in the first device part. A width of a widest part of the first guard ring region is not less than 1.1 times a width of a finest part of the first guard ring region.

### First Embodiment

A first embodiment will now be described.

FIG. 1 is a plan view showing a semiconductor device according to the embodiment.

FIG. 2 is a cross-sectional view showing the semiconductor device according to the embodiment.

The drawings are schematic; and the components are simplified, omitted, or emphasized as appropriate. The numbers and the dimensional ratios of the components do not always match between the drawings. This is similar for the other drawings described below as well.

First, the configuration of the semiconductor device according to the embodiment is summarily described.

As shown in FIG. 1 and FIG. 2, a semiconductor substrate 10 is provided in the semiconductor device 1 according to the embodiment. For example, the semiconductor substrate 10 is made of single-crystal silicon; and the conductivity type of the semiconductor substrate 10 is, for example, a p-type. A semiconductor layer 11 is provided on the semiconductor substrate 10. For example, the semiconductor layer 11 is made of epitaxially-grown single-crystal silicon; and the conductivity type of the semiconductor layer 11 is the p-type.

A device region RD1 and a device region RD2 are set in the semiconductor device 1. Multiple smallest units 50 of a LDMOS (Laterally Double-Diffused MOSFET) are provided in the device region RD1; and a LDMOS 51 is formed of the multiple smallest units 50. The LDMOS 51 is a portion of a large current circuit handling a large current. The large current circuit is, for example, a current control circuit. A small current element 52 is formed in the device region RD2. The small current element 52 is a portion of a small current circuit handling a small current. The small current circuit is, for example, a signal processing circuit, e.g., an analog circuit.

An XYZ orthogonal coordinate system is employed for convenience of description in the specification hereinbelow. Among the directions parallel to an interface 12 between the semiconductor substrate 10 and the semiconductor layer 11, the direction from the device region RD1 toward the device region RD2 is taken as an “X-direction”. Also, among the directions parallel to the interface 12, a direction orthogonal to the X-direction is taken as a “Y-direction”. A direction that is orthogonal to the interface 12 is taken as a “Z-direction”. The Z-direction also is called the “thickness direction” of the semiconductor substrate 10 and the semiconductor layer 11. Although a direction that is in the Z-direction from the semiconductor substrate 10 toward the semiconductor layer 11 also is called “up”, and the reverse direction also is called “down”, these expressions are for convenience and are independent of the direction of gravity.

In the device region RD1, a deep n-type region 15 is provided between the semiconductor substrate 10 and the semiconductor layer 11. The conductivity type of the deep n-type region 15 is an n-type. The deep n-type region 15 is rectangular when viewed from above. As illustrated in a sixth embodiment described below, other than rectangular, the configuration of the deep n-type region 15 may be a polygon or other configuration.

In the device region RD1, n-type regions 16a and 16b are provided on the deep n-type region 15. The n-type region 16a is provided on an end portion of the deep n-type region 15; and the n-type region 16b is provided on a portion other than the end portion of the deep n-type region 15. n-type regions 17a and 17b are provided respectively on the n-type regions 16a and 16b; and n⁺-type contact regions 18a and 18b are provided respectively on the n-type regions 17a and 17b.

The n-type region 16a contacts the end portion of the deep n-type region 15; the n-type region 17a contacts the n-type region 16a; and the n⁺-type contact region 18a contacts the n-type region 17a. A guard ring region 19 of the n-conductivity type is formed of the n-type region 16a, the n-type region 17a, and the n⁺-type contact region 18a. On the other hand, the n-type region 16b contacts the portion other than the end portion of the deep n-type region 15; the n-type region 17b contacts the n-type region 16b; and the n⁺-type contact region 18b contacts the n-type region 17b. A separation region 22 of the n-conductivity type is formed of the n-type region 16b, the n-type region 17b, and the n⁺-type contact region 18b.

When the deep n-type region 15 is rectangular when viewed from above, for example, the guard ring region 19 has a rectangular-frame shape along the edge of the deep n-type region 15. When the deep n-type region 15 is a polygon other than a rectangle, the guard ring region 19 has a configuration along the edge of the polygon. The lower end of the n-type region 16a is connected to the end portion of the deep n-type region 15; and the upper end of the n⁺-type contact region 18a reaches the upper surface of the semiconductor layer 11. As a result, the deep n-type region 15 and the guard ring region 19 surround a portion of the semiconductor layer 11 in a cup configuration. The part of the semiconductor layer 11 surrounded with the deep n-type region 15 and the guard ring region 19 is taken as a device part 21.

The separation region 22 electrically divides the device part 21 into a first region R1 and a second region R2. Hereinbelow, electrically isolating multiple regions from each other also is called “partitioning”. In the embodiment, for example, the separation region 22 has a plate configuration spreading along the YZ plane. The lower end of the separation region 22 is connected to the deep n-type region 15; the upper end of the separation region 22 reaches the upper surface of the semiconductor layer 11; and the two Y-direction end portions of the separation region 22 are connected to the guard ring region 19. The width, i.e., the length in the X-direction, of the separation region 22 is substantially equal to the width of the guard ring region 19. The surface area of the first region R1 is substantially equal to the surface area of the second region R2 when viewed from above. Multiple smallest units 50 of the LDMOS are formed in each of the first region R1 and the second region R2.

Although only two smallest units 50 are shown in each of the first region R1 and the second region R2 for convenience of illustration in FIG. 2, more of the smallest units 50 may be provided in each region; for example, several tens to several hundreds of the smallest units 50 may be provided.

In the device region RD2, the small current element 52 which includes a p-type well 25 and an n-type well 26 is provided in the upper layer part of the semiconductor layer 11. Impurity regions other than the p-type well 25 and the n-type well 26 may be provided in the small current element 52; and insulating members, electrodes, etc., may be provided in the small current element 52. The small current element 52 is separated from the guard ring region 19. The small current element 52 is a portion of the small current circuit described above. A detailed description of the small current circuit is omitted.

A STI (Shallow Trench Isolation (element-separation insulating film)) 55 is provided at the upper layer part of the semiconductor layer 11. The STI 55 is provided between the device region RD1 and the device region RD2. The STI 55 also is provided at the periphery of the first region R1 and the periphery of the second region R2 in the device region RD1. The STI 55 is provided at the periphery of the p-type well 25 and the periphery of the n-type well 26 in the device region RD2. For example, the STI 55 is formed of silicon oxide.

The configuration of the device region RD1 will now be described in detail.

In the embodiment, the configuration of the first region R1 and the configuration of the second region R2 are substantially the same. p-type regions 31 are provided respectively in the first region R1 and the second region R2. The p-type region 31 is a portion of the semiconductor layer 11 and contacts the deep n-type region 15 and the guard ring region 19.

A deep p-type well 30 is provided in the p-type region 31. The impurity concentration of the deep p-type well 30 is greater than the impurity concentration of the p-type region 31. A drift region 33 of the n-conductivity type is provided in the X-direction central part of the upper layer portion of the p-type region 31. The drift region 33 is separated from the deep p-type well 30 by the p-type region 31. The drift region 33 may contact the deep p-type well 30.

A drain extension region 34 of the n-conductivity type is provided in the X-direction central portion of the upper layer portion of the drift region 33; and a drain region 35 of the n⁺-conductivity type is provided in the X-direction central portion of the upper layer portion of the drain extension region 34. The impurity concentration of the drain extension region 34 is greater than the impurity concentration of the drift region 33; and the impurity concentration of the drain region 35 is greater than the impurity concentration of the drain extension region 34.

A p-type region 36 is provided in the X-direction when viewed from the drift region 33; and a source extension region 37 of the n-conductivity type, a source region 38 of the n⁺-conductivity type, and a body contact region 39 of the p⁺-conductivity type are provided in parts of the upper layer portion of the p-type region 36 separated from the p-type region 31.

A gate insulating film 42 and a step insulating film 43 are provided on the semiconductor layer 11. STI may be provided instead of the step insulating film 43. The gate insulating film 42 is provided on the part of the drift region 33 between the step insulating film 43 (or the STI) and the p-type region 36, on the part of the p-type region 31 between the drift region 33 and the p-type region 36, on the part of the p-type region 36 between the p-type region 31 and the source extension region 37, and on the source extension region 37. The step insulating film 43 is provided on a part of the drift region 33 at the drain extension region 34 side. The step insulating film 43 is thicker than the gate insulating film 42. For example, the gate insulating film 42 and the step insulating film 43 are formed of silicon oxide.

A gate electrode 44 is provided on the gate insulating film 42 and on the step insulating film 43. For example, the gate electrode 44 is formed of a conductive material such as polysilicon, a metal silicide, etc.

A sidewall 45a is provided on the side surface of the gate electrode 44. A portion of the sidewall 45a is provided on the step insulating film 43; and another portion of the sidewall 45a is provided on the source extension region 37. A sidewall 45b is provided on the side surface of the step insulating film 43 at the drain side. The sidewall 45b is provided on the drain extension region 34. The sidewalls 45a and 45b are made from insulating materials; for example, the sidewalls 45a and 45b are stacked bodies made of a silicon oxide layer and a silicon nitride layer.

In the first region R1 and the second region R2, the multiple smallest units 50 of the n-type LDMOSs are formed of the p-type region 31, the deep p-type well 30, the drift region 33, the drain extension region 34, the drain region 35, the p-type region 36, the source extension region 37, the source region 38, the body contact region 39, the gate insulating film 42, the step insulating film 43, the gate electrode 44, and the sidewalls 45a and 45b.

The p-type region 36, the source extension region 37, the source region 38, and the body contact region 39 (hereinbelow, generally referred to as the “source regions and the like”) or the drift region 33, the drain extension region 34, and the drain region 35 (hereinbelow, generally referred to as the “drain regions and the like”) may be shared between two smallest units 50 next to each other in the X-direction when many smallest units 50 are provided in the first region R1. In other words, in the first region R1, the source regions and the like and the drain regions and the like may be arranged alternately along the X-direction; and the smallest unit 50 may be formed between the adjacent source regions and the like and drain regions and the like. The source regions and the like and the drain regions and the like may extend along the Y-direction. This is similar for the second region R2 as well.

An inter-layer insulating film 46 is provided on the semiconductor layer 11. The inter-layer insulating film 46 covers the gate insulating film 42, the step insulating film 43, the gate electrode 44, and the sidewalls 45a and 45b. Contacts 47a to 47e and interconnects 48 are provided in the inter-layer insulating film 46. The interconnects 48 are provided on the contacts 47a to 47e.

The contact 47a is connected to the n⁺-type contact region 18a of the guard ring region 19. The contact 47b is connected to the n⁺-type contact region 18a of the separation region 22. The contact 47c is connected to the drain region 35. The contact 47d is connected to the source region 38 and the body contact region 39. The contact 47e is connected to the gate electrode 44. The contacts 47a to 47e are connected respectively to the interconnects 48.

An operation of the semiconductor device 1 according to the embodiment will now be described.

FIG. 3 shows the operation of the semiconductor device 1 according to the embodiment.

The device region RD1 is included in a current control circuit; and the small current element 52 is included in a small current circuit. The small current circuit is, for example, a signal processing circuit, e.g., an analog circuit. Therefore, the current that flows in the n-type well 26 of the small current element 52 is smaller than the current flowing in the p-type region 31 of the LDMOS 51.

Normally, as shown in FIG. 3, for example, a ground potential GND is applied to the source region 38 as a source potential; and a drain potential Vd is applied to the drain region 35. The drain potential Vd is higher than the source potential (GND). A reference potential is applied to the guard ring region 19 via the contact 47a. In the example shown in FIG. 3, the reference potential is the ground potential GND. The reference potential may be a potential other than the ground potential, e.g., the drain potential Vd or a constant potential such as 5 V, etc. The ON/OFF of the LDMOS 51 is controlled by applying a gate potential Vg to the gate electrode 44 via the contact 47e in this state.

However, there are cases where a negative freewheeling current inflows into the drain region 35. For example, the negative freewheeling current is generated in the shoot-through prevention period of an H-bridge output or a step-down circuit of a power supply output. When the negative freewheeling current inflows into the drain region 35, the potential of the drain region 35 becomes lower than the source potential (e.g., the ground potential GND). In such a case, a forward voltage is applied to a parasitic diode 101 made of the p-type region 31 and the n-type drift region 33; and the parasitic diode 101 conducts. Therefore, a current flows in the order of the contact 47d, the body contact region 39, the p-type region 36, the p-type region 31, the drift region 33, the drain extension region 34, the drain region 35, and the contact 47c.

Thereby, the potential of the p-type region 31 drops; a parasitic n-p-n transistor 102 which is formed of the guard-ring and deep n-type regions 19 and 15, the p-type region 31, and the drift region 33 conducts; and a current flows in the order of the contact 47a, the guard-ring and deep n-type regions 19 and 15, the p-type region 31, the drift region 33, the drain extension region 34, the drain region 35, and the contact 47c.

Thereby, the potential of the guard-ring and deep n-type regions 19 and 15 fluctuates. As a result, a parasitic n-p-n transistor 103 which is formed of the n-type well 26, the p-type semiconductor layer 11 and well 25, and the n-type guard-ring and deep n-type regions 19 and 15 conducts; and the potentials of the p-type well 25 and the n-type well 26 fluctuate. The operation of the small current element 52 formed of the p-type well 25 and the n-type well 26 is affected thereby. Because the current that flows in the small current element 52 is smaller than the current flowing in the LDMOS 51, a large effect occurs due to a slight fluctuation of the potential; and misoperations occur easily. Misoperations occur particularly easily when the small current circuit is an analog circuit.

In the embodiment, the same potential as the guard ring region 19, i.e., a reference potential such as the ground potential GND or the like, is applied to the separation region 22 via the contact 47b. Thereby, the potential of the deep n-type region 15 is stable; and the conduction of the parasitic n-p-n transistor 103 is suppressed. As a result, the fluctuation of the potentials of the p-type well 25 and the n-type well 26 is suppressed; and the operation of the small current element 52 is stable.

Effects of the embodiment will now be described.

According to the embodiment, the separation region 22 is provided in the device part 21 and connected to the deep n-type region 15. Therefore, the fluctuation of the potentials of the deep n-type region 15 and the guard ring region 19 is suppressed and the conduction of the parasitic n-p-n transistor 103 is suppressed even when the parasitic diode 101 and the parasitic n-p-n transistor 102 conduct due to the negative freewheeling current flowing into the drain region 35 of the LDMOS 51. The effects on the operation of the small current element 52 can be suppressed thereby. In other words, the interference of the LDMOS 51 on the small current element 52 can be suppressed. As a result, the distance between the device region RD1 and the device region RD2 can be shortened; and downsizing of the semiconductor device 1 can be realized.

### First Modification of First Embodiment

A first modification of the first embodiment will now be described.

FIG. 4 is a plan view showing a semiconductor device according to the modification.

In the semiconductor device 1a according to the modification as shown in FIG. 4, the surface area of the first region R1 is greater than the surface area of the second region R2. For example, the surface area of the first region R1 is 2 times the surface area of the second region R2. Also, the number of the smallest units 50 of the LDMOS provided in the first region R1 is more than, e.g., 2 times the number of the smallest units 50 provided in the second region R2. Thus, the surface area of the second region R2 and the surface area of the first region R1 may be different. Thus, by reducing the number of the smallest units 50 in the second region R2 provided at the device region RD2 side, the effects of the device region RD1 on the device region RD2 can be reduced more effectively. Otherwise, the configuration, the operations, and the effects of the modification are similar to those of the first embodiment.

### Second Modification of First Embodiment

A second modification of the first embodiment will now be described.

FIG. 5 is a plan view showing a semiconductor device according to the modification.

In the semiconductor device 1b according to the modification as shown in FIG. 5, the separation region 22 has a plate configuration spreading along the XZ plane; and the first region R1 and the second region R2 are arranged along the Y-direction. The arrangement direction of the first region R1 and the second region R2 is not limited and may be a direction other than the X-direction and the Y-direction. Otherwise, the configuration, the operations, and the effects of the modification are similar to those of the first embodiment.

### Third Modification of First Embodiment

A third modification of the first embodiment will now be described.

FIG. 6 is a plan view showing a semiconductor device according to the modification.

In the semiconductor device 1c according to the modification as shown in FIG. 6, two of the separation regions 22 are provided to be separated from each other. The two separation regions 22 are arranged in the X-direction, The separation regions 22 each have plate configurations spreading along the YZ plane. Thereby, the separation regions 22 partition the device part 21 into the three regions of the first region R1, the second region R2, and a third region R3. The first region R1, the second region R2, and the third region R3 are arranged in this order along the X-direction. However, the arrangement direction is not limited thereto. The surface area of the first region R1, the surface area of the second region R2, and the surface area of the third region R3 may be different from each other. For example, the surface area of the second region R2 may be greater than the surface area of the first region R1 and the surface area of the third region R3; or the third region R3, the second region R2, and the first region R1 may become larger in this order.

The configurations of the first region R1 and the second region R2 are similar to those of the first embodiment. The configuration of the third region R3 is similar to the configuration of the first region R1. In other words, the p-type region 31, etc., are provided and the multiple smallest units 50 are formed also in the third region R3. Otherwise, the configuration, the operations, and the effects of the modification are similar to those of the first embodiment.

### Fourth Modification of First Embodiment

A fourth modification of the first embodiment will now be described.

FIG. 7 is a plan view showing a semiconductor device according to the modification.

In the semiconductor device id according to the modification as shown in FIG. 7, three of the separation regions 22 are provided to be separated from each other. The three separation regions 22 are arranged in the X-direction. The separation regions 22 each have plate configurations spreading along the YZ plane. Thereby, the separation regions 22 partition the device part 21 into the four regions of the first region R1, the second region R2, the third region R3, and a fourth region R4. The first region R1, the second region R2, the third region R3, and the fourth region R4 are arranged in this order along the X-direction. However, the arrangement direction is not limited thereto.

The configurations of the first region R1 and the second region R2 are similar to those of the first embodiment. The configurations of the third region R3 and the fourth region R4 are similar to the configuration of the first region R1. In other words, the p-type region 31, etc., are provided and the multiple smallest units 50 are formed also in the third region R3 and the fourth region R4. Otherwise, the configuration, the operations, and the effects of the modification are similar to those of the first embodiment. The surface area of the first region R1, the surface area of the second region R2, the surface area of the third region R3, and the surface area of the fourth region R4 may be different from each other.

### Fifth Modification of First Embodiment

A fifth modification of the first embodiment will now be described.

FIG, 8 is a plan view showing a semiconductor device according to the modification.

In the semiconductor device 1e according to the modification as shown in FIG. 8, the separation region 22 has a cross-shape when viewed from above. In other words, the separation region 22 includes a plate-shaped part spreading along the YZ plane and a plate-shaped part spreading along the XZ plane. Thereby, the separation region 22 partitions the device part 21 into the four regions of the first region R1, the second region R2, the third region R3, and the fourth region R4. The first region R1, the second region R2, the third region R3, and the fourth region R4 are arranged in a matrix configuration having two rows and two columns along the X-direction and the Y-direction. However, the arrangement direction is not limited thereto. Otherwise, the configuration, the operations, and the effects of the modification are similar to those of the fourth modification of the first embodiment.

### Sixth Modification of First Embodiment

A sixth modification of the first embodiment will now be described.

FIG. 9 is a plan view showing a semiconductor device according to the modification.

As shown in FIG. 9, the semiconductor device 1f according to the modification differs from the semiconductor device 1e according to the fifth modification (referring to FIG. 8) in that the width of the separation region 22 is less than the width of the guard ring region 19. For example, the width of the separation region 22 is not more than half of the width of the guard ring region 19.

Thereby, the surface area of the device region RD1 can be reduced while stabilizing the potentials of the deep n-type region 15 and the guard ring region 19; and the semiconductor device 1f can be downsized further. Otherwise, the configuration, the operations, and the effects of the modification are similar to those of the fifth modification of the first embodiment.

### Second Embodiment

A second embodiment will now be described.

FIG. 10 is a plan view showing a semiconductor device according to the embodiment.

FIG. 11 is a cross-sectional view showing the semiconductor device according to the embodiment.

As shown in FIG. 10 and FIG. 11, the semiconductor device 2 according to the embodiment differs from the semiconductor device 1 according to the first embodiment (referring to FIG. 1 and FIG. 2) in that the small current element 52 is formed not in the device region RD2 but in the second region R2 of the device region RD1. In the semiconductor device 2, the configuration of the first region R1 is similar to that of the first embodiment.

In the second region R2, the p-type region 31 is provided; and the p-type well 25 and the n-type well 26 are provided on the p-type region 31. The p-type well 25 and the n-type well 26 are portions of the small current element 52; and the small current element 52 is a portion of a small current circuit. The small current circuit is, for example, a signal processing circuit, e.g., an analog circuit. The current that flows through the p-type region 31 of the second region R2 is smaller than the current flowing through the p-type region 31 of the first region R1.

By providing the separation region 22 according to the embodiment, the effects on the operation of the small current element 52 of the noise generated in the LDMOS 51 can be suppressed. Also, the semiconductor device 2 can be downsized further because the LDMOS 51 and the small current element 52 can be provided in one device region RD1. Otherwise, the configuration, the operations, and the effects of the embodiment are similar to those of the first embodiment.

### Third Embodiment

A third embodiment will now be described.

FIG. 12 is a plan view showing a semiconductor device according to the embodiment.

FIG. 13 is a cross-sectional view showing the semiconductor device according to the embodiment.

As shown in FIG. 12 and FIG. 13, the semiconductor device 3 according to the embodiment differs from the semiconductor device 1 according to the first embodiment (referring to FIG. 1 and FIG. 2) in that the small current elements 52 are formed in both the first region R1 and the second region R2.

In the semiconductor device 3, the p-type regions 31 are provided respectively in the first region R1 and the second region R2. The deep p-type well 30 is provided between the deep n-type region 15 and the p-type region 31. The impurity concentration of the deep p-type well 30 is greater than the impurity concentration of the p-type region 31. The p-type well 25 and the n-type well 26 are provided on the p-type region 31. The p-type well 25 and the n-type well 26 are portions of the small current element 52; and the small current element 52 is a portion of a small current circuit. The small current circuit is, for example, a signal processing circuit, e.g., an analog circuit.

In the embodiment, by surrounding the small current circuit with the deep n-type region 15 and the guard ring region 19, the effects on the small current circuit can be suppressed even when noise inflows from a circuit (not illustrated) provided outside the device region RD1. By providing the separation region 22, the p-type well 25 and the n-type well 26 can be provided together in one device region RD1 even in the case where the potentials are different between the p-type well 25 in the first region R1 and the p-type well 25 in the second region R2 or the potentials are different between the n-type well 26 in the first region R1 and the n-type well 26 in the second region R2; and the semiconductor device 3 can be downsized. Otherwise, the configuration, the operations, and the effects of the embodiment are similar to those of the first embodiment.

### Fourth Embodiment

A fourth embodiment will now be described.

FIG. 14 is a plan view showing a semiconductor device according to the embodiment.

As shown in FIG. 14, the configuration of the device region RD2 of the semiconductor device 4 according to the embodiment is different from that of the semiconductor device le according to the fifth modification of the first embodiment (referring to FIG. 8).

In the device region RD2 of the semiconductor device 4, a deep n-type region 61 is provided between the semiconductor substrate 10 and the semiconductor layer 11; and an n-type guard ring region 62 is provided on the end portion of the deep n-type region 61. When viewed from above, for example, the deep n-type region 61 is rectangular; and the guard ring region 62 is frame-shaped. A device part 63 of the semiconductor layer 11 is surrounded with the deep n-type region 61 and the guard ring region 62.

A separation region 64 is provided in the device region RD2. The separation region 64 has a cross-shape when viewed from above. The width of the separation region 64 in the device region RD2 is less than the width of the separation region 22 in the device region RD1 when viewed from above. The width of the separation region 64 may be the same as or greater than the width of the separation region 22. The width of the guard ring region 62 in the device region RD2 may be less than the width of the guard ring region 19 in the device region RD1. The surface area of the device region RD2 may be less than the surface area of the device region RD1 when viewed from above.

The device part 63 is partitioned by the separation region 64 into four regions, i.e., a fifth region R5, a sixth region R6, a seventh region R7, and an eighth region R8. The fifth region R5, the sixth region R6, the seventh region R7, and the eighth region R8 are arranged in a matrix configuration having two rows and two columns along the X-direction and the Y-direction.

The configurations of the fifth region R5, the sixth region R6, the seventh region R7, and the eighth region R8 are similar to the second region R2 of the third embodiment. In other words, the p-type region 31, etc., are provided and the small current element 52 is formed in each of the fifth region R5, the sixth region R6, the seventh region R7, and the eighth region R8. The small current element 52 is included in a small current circuit. The small current circuit is, for example, a signal processing circuit, e.g., an analog circuit.

On the other hand, in the device region RD1, the LDMOS 51 is formed and is included in a current control circuit. Therefore, the current that flows through the p-type region 31 provided in the device region RD2 is smaller than the current flowing through the p-type region 31 provided in the device region RD1. Otherwise, the configuration, the operations, and the effects of the embodiment are similar to those of the fifth modification of the first embodiment.

### Fifth Embodiment

A fifth embodiment will now be described.

FIG. 15A is a plan view showing a semiconductor device according to the embodiment; and FIG. 15B is a cross-sectional view of the semiconductor device according to the embodiment.

As shown in FIGS. 15A and 15B, the semiconductor device 5 according to the embodiment differs from the semiconductor device 1 according to the first embodiment (referring to FIG. 1 and FIG. 2) in that the separation region 22 is not provided; the width of the guard ring region 19 is nonuniform; and a width W1 of the widest part of the guard ring region 19 is not less than 1.1 times a width W2 of the finest part of the guard ring region 19.

For example, when viewed from above, the guard ring region 19 is frame-shaped and includes four side portions 19a, 19b, 19c, and 19d. The width of one side portion 19a is wider than the widths of the other three side portions 19b, 19c, and 19d. The maximum width at the side portion 19a is the width W1; and the minimum width at the side portions 19b, 19c, and 19d is the width W2. As described above, the width W1 is not less than 1.1 times the width W2, e.g., not less than 2 times the width W2. For example, among the four side portions, the side portion 19a is the side portion most proximal to the device region RD2.

According to the embodiment, the wide side portion 19a of the guard ring region 19 has a low resistance; therefore, the ground potential GND can be applied efficiently to the deep n-type region 15 via the side portion 19a. The fluctuation of the potentials of the deep n-type region 15 and the guard ring region 19 can be suppressed thereby.

Similarly to the first embodiment, the small current element 52 which includes the p-type well 25 and the n-type well 26 is provided in the device region RD2. The small current element 52 is included in a small current circuit such as a signal processing circuit, an analog circuit, etc. The current that flows in the n-type well 26 of the device region RD2 is smaller than the current flowing through the p-type region 31 of the device region RD1.

Otherwise, the configuration, the operations, and the effects of the embodiment are similar to those of the first embodiment. Although an example is shown in the embodiment in which one of the four side portions of the guard ring region 19 is wide, two or three side portions may be wide. The widest side portion may not always be the side portion most proximal to the device region RD2.

### Sixth Embodiment

A sixth embodiment will now be described.

FIG. 16 is a plan view showing a semiconductor device according to the embodiment.

As shown in FIG. 16, the semiconductor device 6 according to the embodiment differs from the semiconductor device 1 according to the first embodiment (referring to FIG. 1 and FIG. 2) in that the length of the second region R2 is less than the length of the first region R1 in the Y-direction; and the overall shape of the device region RD1 when viewed from above is a polygon other than a rectangle, e.g., an L-shape.

In the embodiment, when viewed from above, the deep n-type region 15 is L-shaped; and the guard ring region 19 is an L-shaped frame. The length of the separation region 22 in the Y-direction is less than that of the semiconductor device 1 according to the first embodiment. The device region RD1 is not limited to an L-shape and may be another polygon. Otherwise, the configuration, the operations, and the effects of the embodiment are similar to those of the first embodiment.

### Seventh Embodiment

A seventh embodiment will now be described.

FIG. 17 is a plan view showing a semiconductor device according to the embodiment.

As shown in FIG. 17, the semiconductor device 7 according to the embodiment differs from the semiconductor device 1 according to the first embodiment (referring to FIG. 1 and FIG. 2) in that the first region R1 is a polygon other than a rectangle, e.g., an L-shape.

More specifically, the length of the second region R2 is less than the length of the first region R1 in both the X-direction and the Y-direction. The second region R2 is rectangular when viewed from above. On the other hand, the first region R1 has an L-shape opposing two sides of the second region R2. The guard ring region 19 also has an L-shape when viewed from above. When viewed from above, the deep n-type region 15 is rectangular; and the guard ring region 19 has a rectangular-frame shape. Otherwise, the configuration, the operations, and the effects of the embodiment are similar to those of the first embodiment.

According to the embodiments described above, a semiconductor device can be realized in which downsizing is possible.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Additionally, the embodiments described above can be combined mutually.

What is claimed is:

1. A semiconductor device, comprising:
a semiconductor substrate of a first conductivity type;
a semiconductor layer provided on the semiconductor substrate, the semiconductor layer being of the first conductivity type;
a first deep semiconductor region provided between the semiconductor substrate and the semiconductor layer, the first deep semiconductor region being of a second conductivity type;
a first guard ring region of the second conductivity type, the first guard ring region and the first deep semiconductor region surrounding a first device part of the semiconductor layer;
a first separation region contacting the first guard ring region and the first deep semiconductor region, partitioning the first device part into a first region and a second region, and being of the second conductivity type;
a first semiconductor region provided in the first region, the first semiconductor region being of the first conductivity type; and
a second semiconductor region provided in the second region, the second semiconductor region being of the first conductivity type.

2. The semiconductor device according to claim 1, wherein a width of the first separation region is less than a width of the first guard ring region.

3. The semiconductor device according to claim 1, further comprising:
a first source region provided in the first region, the first source region being of the second conductivity type;
a first drain region provided in the first region and separated from the first source region, the first drain region being of the second conductivity type;
a first gate insulating film provided on the first region; and
a first gate electrode provided on the first gate insulating film.

4. The semiconductor device according to claim 3, wherein a current flowing in the second semiconductor region is smaller than a current flowing in the first semiconductor region.

5. The semiconductor device according to claim 3, wherein an analog circuit is formed in the second region.

6. The semiconductor device according to claim 3, further comprising:
a second source region provided in the second region, the second source region being of the second conductivity type;
a second drain region provided in the second region and separated from the second source region, the second drain region being of the second conductivity type;
a second gate insulating film provided on the second region; and
a second gate electrode provided on the second gate insulating film.

7. The semiconductor device according to claim 6, further comprising a third semiconductor region of the semiconductor layer, the third semiconductor region being of the second conductivity type and being provided outside the first guard ring region,
a current flowing in the third semiconductor region is smaller than a current flowing in the first semiconductor region.

8. The semiconductor device according to claim 6, further comprising:
a second deep semiconductor region provided between the semiconductor substrate and the semiconductor layer and separated from the first deep semiconductor region, the second deep semiconductor region being of the second conductivity type;
a second guard ring region of the second conductivity type, the second guard ring region and the second deep semiconductor region surrounding a second device part of the semiconductor layer;
a second separation region contacting the second guard ring region and the second deep semiconductor region, partitioning the second device part into a third region and a fourth region, and being of the second conductivity type;
a third semiconductor region provided in the third region, the third semiconductor region being of the first conductivity type; and
a fourth semiconductor region provided in the fourth region, the fourth semiconductor region being of the first conductivity type,
a current flowing in the third semiconductor region and a current flowing in the fourth semiconductor region are smaller than a current flowing in the first semiconductor region and a current flowing in the second semiconductor region.

9. The semiconductor device according to claim 8, wherein analog circuits are formed respectively in the third region and the fourth region.

10. The semiconductor device according to claim 8, wherein a width of the second guard ring region is less than a width of the first guard ring region.

11. The semiconductor device according to claim 1, further comprising a third semiconductor region of the first conductivity type,
the first separation region partitioning the first device part into the first region, the second region, and a third region,
the third semiconductor region being provided in the third region.

12. The semiconductor device according to claim 1, further comprising:
a third semiconductor region of the first conductivity type; and
a fourth semiconductor region of the first conductivity type,
the first separation region partitioning the first device part into the first region, the second region, a third region, and a fourth region,
the third semiconductor region being provided in the third region,
the fourth semiconductor region being provided in the fourth region.

13. The semiconductor device according to claim 12, wherein the first region, the second region, the third region, and the fourth region are arranged along one direction.

14. The semiconductor device according to claim 12, wherein the first region, the second region, the third region, and the fourth region are arranged in a matrix configuration.

15. The semiconductor device according to claim 1, further comprising:
a second deep semiconductor region provided in the first region, the second deep semiconductor region being of the first conductivity type; and
a third deep semiconductor region provided in the second region, the third deep semiconductor region being of the first conductivity type.

16. The semiconductor device according to claim 1, further comprising:
a first contact connected to the first guard ring region; and
a second contact connected to the first separation region.

17. A semiconductor device, comprising:
a semiconductor substrate of a first conductivity type;
a semiconductor layer provided on the semiconductor substrate, the semiconductor layer being of the first conductivity type;
a first deep semiconductor region provided between the semiconductor substrate and the semiconductor layer, the first deep semiconductor region being of a second conductivity type;
a first guard ring region of the second conductivity type, the first guard ring region and the first deep semiconductor region surrounding a first device part of the semiconductor layer; and
a first semiconductor region provided in the first device part, the first semiconductor region being of the first conductivity type,
a width of a widest part of the first guard ring region being not less than 1.1 times a width of a finest part of the first guard ring region.

18. The semiconductor device according to claim 17, wherein
the first guard ring region has a rectangular-frame shape including four side portions when viewed from above, and
a width of a first of the side portions is wider than widths of a second, a third, and a fourth of the side portions.

19. The semiconductor device according to claim 17, further comprising:
a first source region provided in the first device part, the first source region being of the second conductivity type;
a first drain region provided in the first device part and separated from the first source region, the first drain region being of the second conductivity type;
a first gate insulating film provided on the first device part; and
a first gate electrode provided on the first gate insulating film.

20. The semiconductor device according to claim 17, further comprising a second semiconductor region of the semiconductor layer, the second semiconductor region being provided outside the first guard ring region and being of the second conductivity type,
a current flowing in the second semiconductor region is smaller than a current flowing in the first semiconductor region.

21. The semiconductor device according to claim 20, wherein the second semiconductor region is included in an analog circuit.

22. The semiconductor device according to claim 17, further comprising a second deep semiconductor region provided in the first device part and provided on the first deep semiconductor region, the second deep semiconductor region being of the first conductivity type.
